(19) United States
(12) Patent Application Publication
(10) Pub. No.: US 2009/0130808 A1
(43) Pub. Date: May 21, 2009

(54) METHOD OF FABRICATING FLASH MEMORY

(76) Inventors: Chao-Yuan Lo, Hsinchu County (TW); Rex Young, Hsinchu City (TW); Pin-Yao Wang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/942,718

(22) Filed: Nov. 20, 2007

(51) Int. Cl. H01L 21/336

(52) U.S. Cl. 438/257; 257/E21.409

(57) ABSTRACT

A method of fabricating a flash memory includes successively forming a floating gate insulating layer, a floating gate material layer, a dielectric layer, a control gate material layer, a silicide layer, and a hard mask layer on a semiconductor substrate, patterning the hard mask layer, removing portions of the silicide layer, the control gate material layer, the dielectric layer, and the floating gate material layer not covered by the hard mask layer to form a stacked structure, forming a silicon cap layer covering the surface of the stacked structure, and performing a thermal process.

### BACKGROUND OF THE INVENTION

1. Field of the Invention

The present invention relates to a method of fabricating a flash memory, and more particularly, to a method of fabricating a flash memory by utilizing a silicon cap layer to improve the structure and performance of the flash memory.

2. Description of the Prior Art

Because a nonvolatile memory cell is rewritable and has qualities as fast transfer and low power consumption, it has been widely applied to products of various fields and become a critical device of many information, communication, and consuming electronic products. However, in order to provide light electronic products with high quality, it has become important for the current information industry and memory manufacturers to increase the device integration and quality of the nonvolatile memory cells.

Please refer to FIGS. 1-2. FIGS. 1-2 are schematic diagrams of a fabrication method of a stack-gate flash memory 10 according to the prior art. As shown in FIG. 1, first, a semiconductor substrate 12 is provided. Second, an oxide layer 14 is formed on the surface of the semiconductor substrate 12. Through several deposition processes, photolithography processes, and etching processes, a plurality of stacked structures 28 is formed on the surface of the semiconductor substrate 12, wherein one stacked structure 28 comprises a floating gate 16, a dielectric layer 18, a control gate 20, a silicide layer 22, and a hard mask layer 24 from bottom to top. Generally, the silicide layer 22 is a tungsten silicide (WSi) layer, and the silicide layer 22 and the control gate 20 composed of polysilicon material may be considered together as a word line of the stack-gate flash memory 10. The word line plays an important role in the speed of writing, erase, and reading of the stack-gate flash memory 10. However, the silicide layer 22 fabricated by the above-mentioned processes has a high sheet resistance (Rs) value, and therefore an appropriate thermal process is performed, after the stacked structures 28 are formed, for varying the distribution of the silicon and tungsten atoms therein in order to reduce the value of the sheet resistance.

Accordingly, after the stacked structures 28 are formed, the thermal process will be performed to oxidize the surfaces of the stacked structures 28 and to form an oxide layer 26. However, as shown in FIG. 2, an unsuitable thermal process will cause side effect to erode portions of the silicide layer 22 and cause abnormal oxidization of the sidewall of the stacked structures 28 such that the oxide layer 26 with an abnormal large thickness is formed on the sidewall of the silicide layer 22 for example. Under this situation, voids are easily formed between adjacent stacked structures 28, resulting in that the following formed materials cannot fully fill in the area between the stacked structures 28. Furthermore, mist may permeate into the voids, which effectively influences the reliability of the stack-gate flash memory 10. In addition, the thermal process also reduces the adhesion of the silicide layer 22, thus the word line easily peels off.

As a result, although the prior arts provide the thermal process for reducing the sheet resistance of the word line, an unsuitable thermal process may even cause the problems such as voids occurring, silicide layer 22 being oxidized or nitrified that makes the word line peel off, increase the sheet resistance, or lower the reliability of the stack-gate flash memory 10. As a result, usually, it has to take quite a lot of time for finding a proper recipe of the thermal process in order to improve the quality of the stack-gate flash memory, which is not economic at all. Therefore, how to fabricate a stack-gate flash memory with a low sheet resistance value by a simple method for avoiding the above-mentioned problems caused by the thermal process and for improving the whole operation performance and reliability of the stack-gate flash memory is still an important issue for the manufacturers.

### SUMMARY OF THE INVENTION

It is a primary objective of the claimed invention to provide a method of fabricating a flash memory by utilizing a silicon cap layer for improving the operation performance of the memory.

According to the claimed invention, a method of fabricating a flash memory comprises providing a semiconductor substrate, successively forming a floating gate insulating layer, a floating gate material layer, a dielectric layer, a control gate material layer, a silicide layer, and a hard mask layer on the semiconductor substrate, patterning the hard mask layer to form a control gate pattern on the hard mask layer, removing portions of the silicide layer, the control gate material layer, the dielectric layer, and the floating gate material layer not covered by the patterned hard mask layer to form a stacked structure; forming a silicon cap layer on the semiconductor substrate to cover the surface of the stacked structure; and performing a thermal process.

According to the claimed invention, a fabrication method of a flash memory is further provided. The fabrication method comprises providing a semiconductor substrate; successively forming a floating gate insulating layer, a floating gate material layer, a dielectric layer, a control gate material layer, a silicide layer, and a hard mask layer on the surface of the semiconductor substrate; patterning the hard mask layer to form a control gate pattern on the hard mask layer; removing portions of the silicide layer and the control gate material layer not covered by the patterned hard mask layer until the dielectric layer is exposed so that to form the control gate material layer into a control gate; forming a silicon cap layer on the semiconductor substrate to cover the surfaces of the sidewalls of the silicide layer and the control gate; and performing a thermal process.

It is an advantage of the claimed invention that a silicon cap layer is formed on the sidewall surface of the silicide layer prior to performing the thermal process for oxidizing the silicon cap layer into an oxide layer, such that the structure of the silicide layer can be effectively protected to prevent the silicide layer from damaging or erosion during subsequent processes and from abnormal oxidizing during the thermal or other processes to influence the performance of the flash memory. In addition, the fabrication method of the claimed invention also improves the silicon/tungsten distribution ratio by the thermal process and the problem of high sheet resistance of the word line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 are schematic diagrams of a fabrication method of a stack-gate flash memory according to the prior art.

FIGS. 3-8 are process schematic diagrams of the fabrication method of a flash memory according to a first embodiment of the present invention.

FIGS. 9-14 are process schematic diagrams of the fabrication method of a flash memory according to a second embodiment of the present invention.

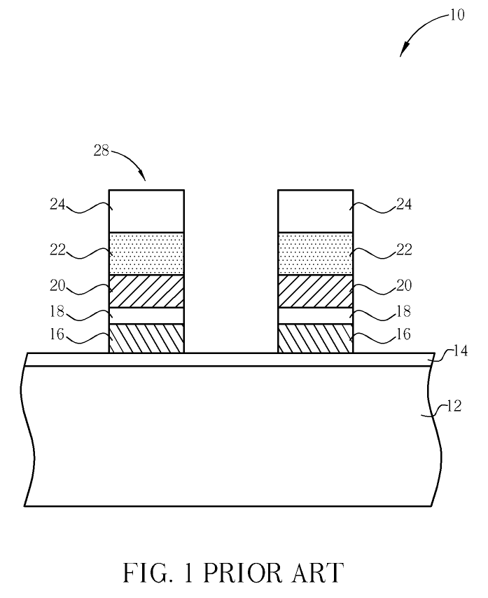

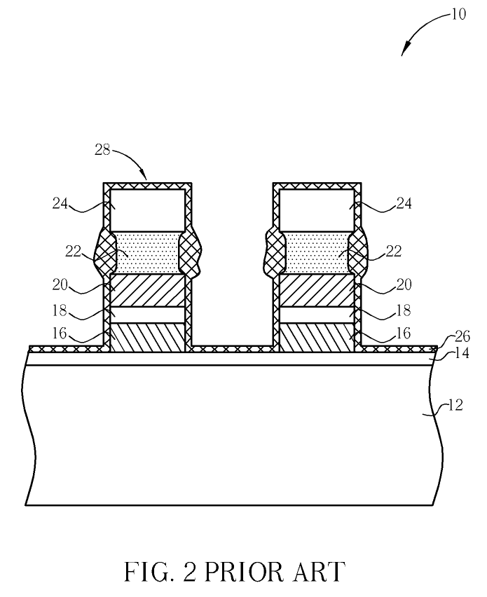

### DETAILED DESCRIPTION

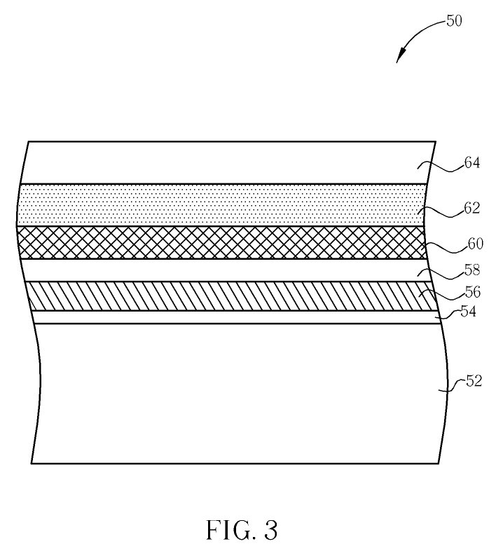

Referring to FIGS. 3-8, FIGS. 3-8 are process schematic diagrams of the fabrication method of a flash memory 50 according to a first embodiment of the present invention. The present flash memory 50 is a stack-gate flash memory. First, as shown in FIG. 3, a semiconductor substrate 52 is provided, which may be a silicon substrate. An oxidization process is carried out to form an oxide layer on the surface of the semiconductor substrate 52, wherein the oxide layer serves as a floating gate insulating layer 54. Then, a floating gate material layer 56, a dielectric layer 58, a control gate material layer 60, a silicide layer 62, and a hard mask layer 64 are successively formed on the surface of the semiconductor substrate 52. The floating gate material layer 56 and the control gate material layer 60 preferably comprise polysilicon material layer respectively, and the silicide layer 62 may comprise tungsten silicide material. The hard mask layer 64 may comprise silicon nitride material, while the dielectric layer 58 preferably comprises oxide-nitride-oxide (ONO) or nitride-oxide-nitride-oxide-nitride (NONON) materials. In addition, before the dielectric layer 58 is formed, a photolithography-etching-process (PEP) may be performed to remove a portion of the floating gate material layer 56 to define a partial pattern of a floating gate (not shown).

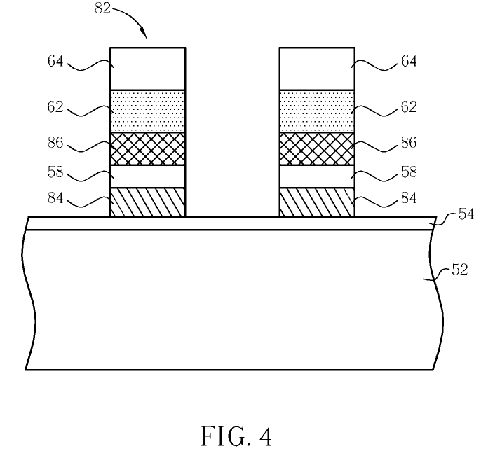

Then, as shown in FIG. 4, the hard mask layer 64 is patterned, and the hard mask layer 64 is taken as a mask of an etching process to remove portions of the silicide layer 62, the control gate material layer 60, the dielectric layer 58, and the floating gate material layer 56 not covered by the patterned hard mask layer 64 so as to form at least a stacked structure 82 (there are two stacked structures 82 shown in FIG. 4), forming the remaining floating gate material layer 56 and control gate material layer 60 into a floating gate 84 and a control gate 86 respectively.

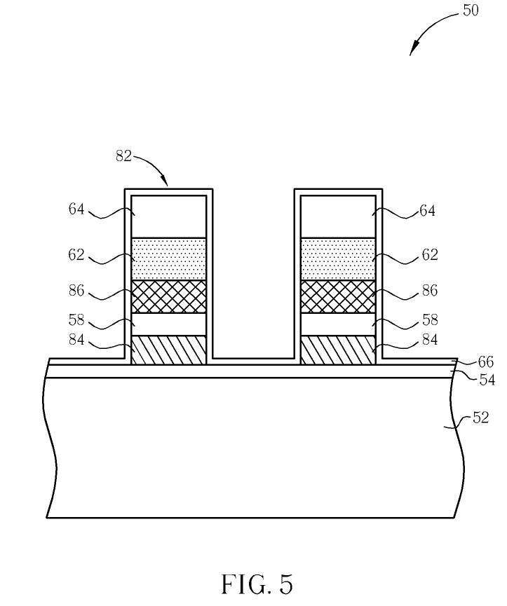

Please refer to FIG. 5. A silicon cap layer 66 is formed on the surface of the semiconductor substrate 52 that covers the stacked structures 82 and the floating gate insulating layer 54 in a conformal way. The formation method of the silicon cap layer 66 may comprise furnace deposition, chemical vapor deposition (CVD), or epitaxial growth processes, wherein the furnace deposition and CVD processes are preferable, and the process temperature is less than or equal to about 600° C. Accordingly, the silicon cap layer 66 may comprise epitaxial silicon, polysilicon, or amorphous silicon materials.

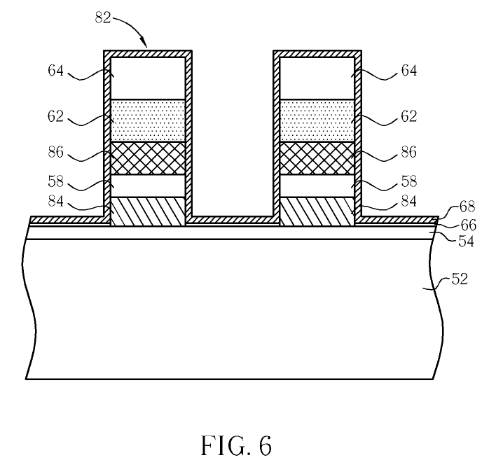

Thereafter, as shown in FIG. 6, a thermal process is carried out with a process temperature of about 900 to 1050° C. to adjust the electricity quality of the silicide layer 62 and further reduce the sheet resistance value of the word lines. During the thermal process, the silicon cap layer 66 may be oxidized and therefore an oxide layer 68 is formed on the top surface of the silicon cap layer 66.

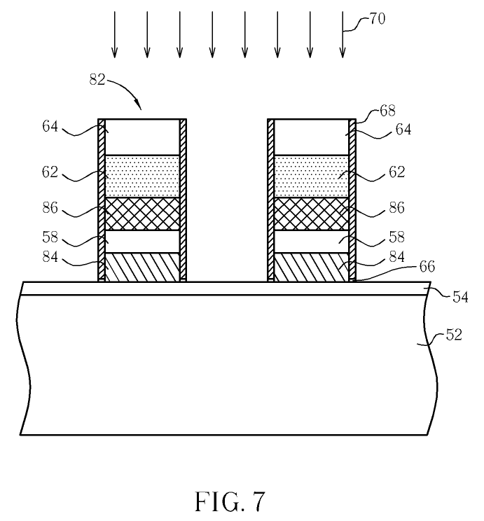

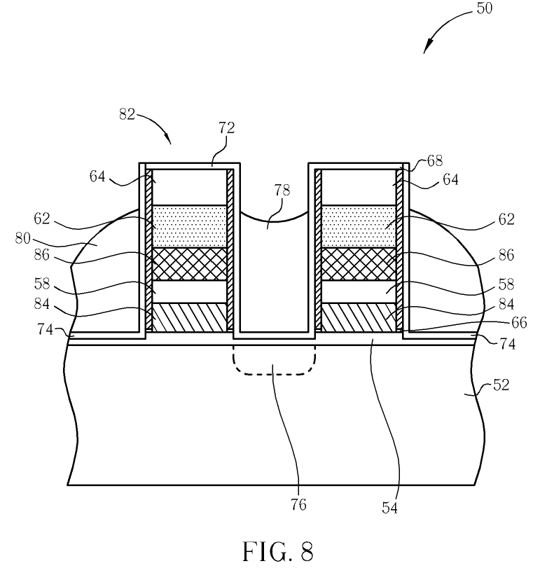

Referring to FIG. 7, an anisotropic etching process 70 is performed to remove the silicon cap layer 66 and the oxide layer 68 remaining right on the surface of the floating gate insulating layer 54 and on the surface of the hard mask layer 64, in order to prevent electrical connection occurring between adjacent stacked structures 82. Please refer to FIG. 8, an erase gate insulating layer 72, a source 76, a word line dielectric layer 74, a erase gate 78, and word line gates 80 may be formed on the surface of the semiconductor substrate 52 to complete the fabrication of the main devices of the flash memory 50.

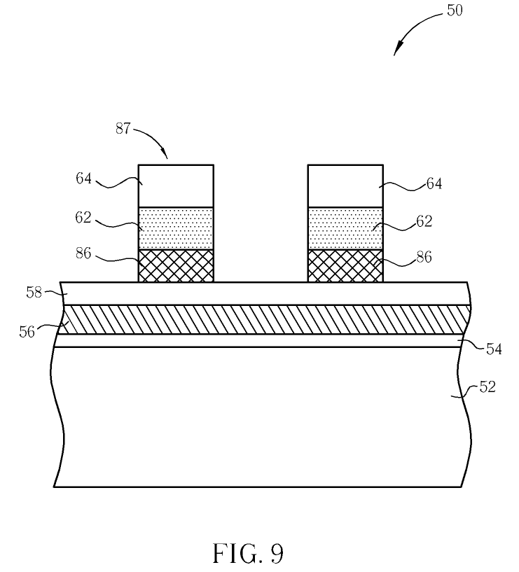

FIGS. 9-12 are process schematic diagrams of the fabrication method of a flash memory according to a second embodiment of the present invention. Some devices in FIGS. 9-12 are indicated by the same numerals as those used in FIGS. 3-8 for simplifying the description, and FIG. 9 illustrates a subsequent process and structure profile of the flash memory 50 of FIG. 3. A floating gate material layer 56, a dielectric layer 58, a control gate material layer 60, a silicide layer 62, and a hard mask layer 64 are successively formed on the semiconductor substrate 52, wherein the dielectric layer 58 may be an ONO dielectric layer or a NONON dielectric layer. Then, as shown in FIG. 9, an photolithography process is performed to pattern the hard mask layer 64 so that the hard mask layer 64 has at least a control gate pattern 87. Sequentially, the patterned hard mask layer 64 is taken as a mask for performing an etching process to the silicide layer 62 and the control gate material layer 60 until the top surface of the dielectric layer 58 is exposed. After the etching process, the remaining control gate material layer 60 forms at least a control gate 86.

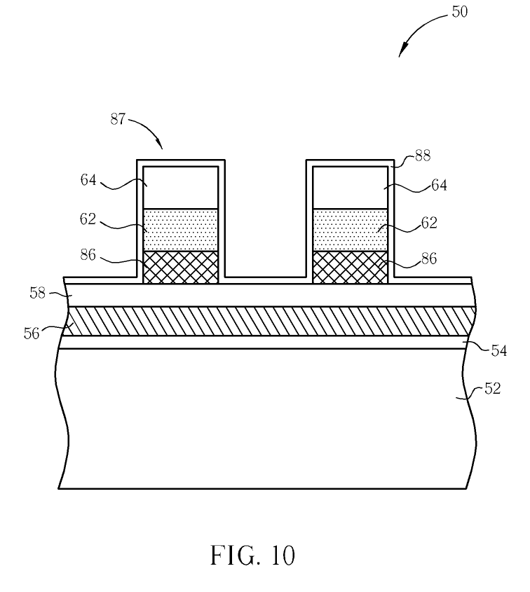

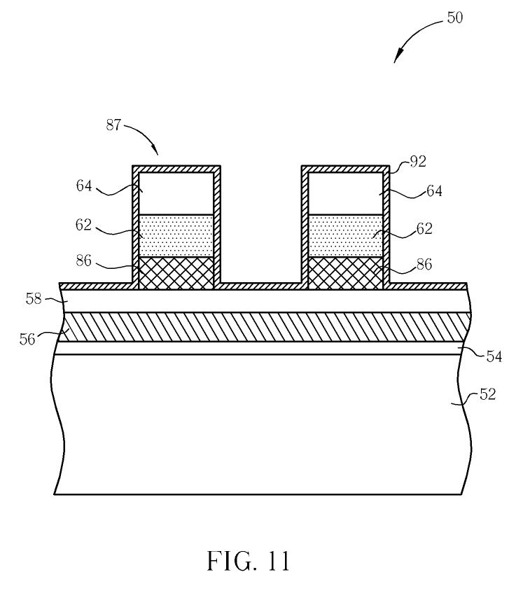

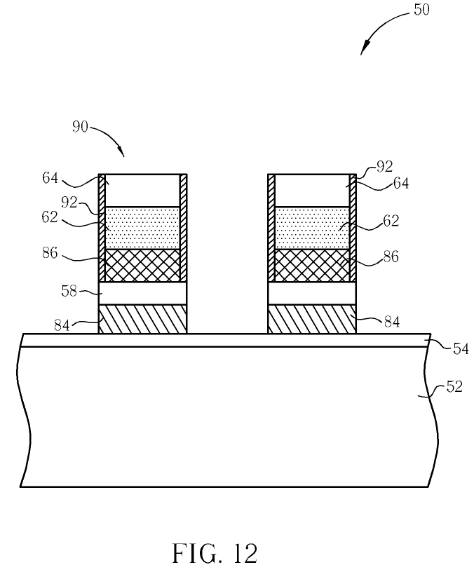

Referring to FIG. 10, a silicon cap layer 88 is blanket formed on the surface of the semiconductor substrate 52, covering the surfaces of the patterned hard mask layer 64, the silicide layer 62, and the control gates 86 and the dielectric layer 58. The formation method of the silicon cap layer 88 may comprise furnace deposition, CVD, or epitaxial growth processes. As a result, the material of the silicon cap layer 88 may comprise epitaxial silicon, polysilicon, or amorphous silicon materials. Then, as shown in FIG. 11, a thermal process is performed to adjust the distribution ratio of the silicon atoms and tungsten atoms of the silicide layer 62, so as to reduce the sheet resistance of the silicide layer 62 or the word lines. In addition, during the thermal process, the silicon cap layer 88 is also oxidized to form an oxide layer 92. Referring to FIG. 12, an anisotropic etching process is carried out to remove portions of the dielectric layer 58 and the floating gate material layer 56 not covered by the patterned hard mask layer 64, which forms at least a stacked structure 90. This etching process may further remove portions of the oxide layer 92 and the patterned hard mask layer 64. The remaining floating gate material layer 56 of each stacked structure 90 is considered as a floating gate 84. Thereafter, floating gate insulating layer, word line dielectric layer, erase gate, word line gate and connecting plug of electrical devices are continuously fabricated on the semiconductor substrate 52. Since the structures of these electrical devices may be similar to those in the first embodiment of the present invention, a detailed description or figures will not be illustrated herein.

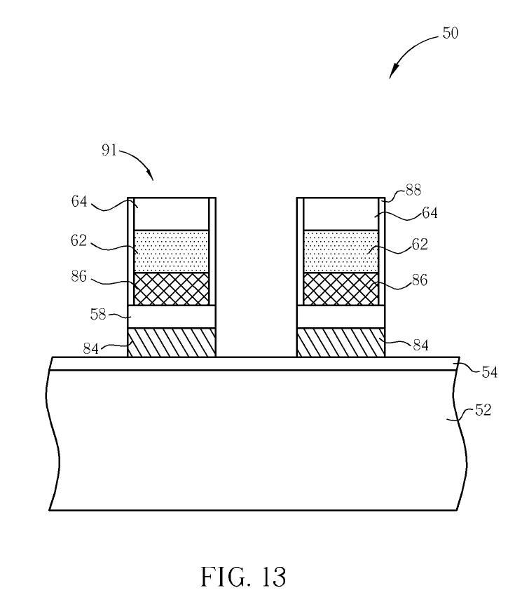

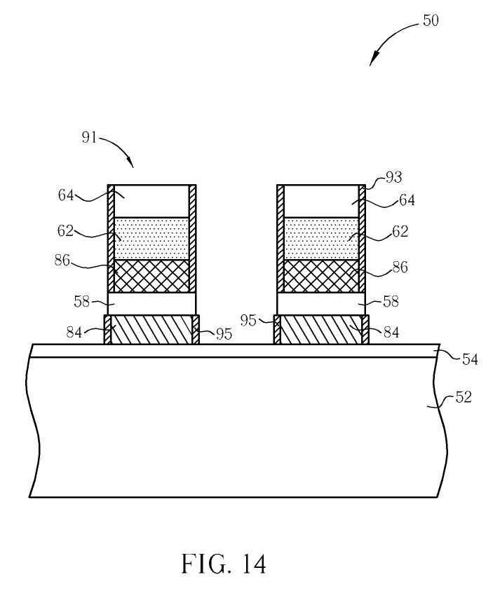

It should be noted that the performing sequence of the thermal process and the anisotropic etching process might be exchanged according to the second embodiment of the present invention. For example, after the silicon cap layer 88 is formed, the anisotropic etching process may be performed to define the floating gates 84 before performing the thermal process for adjusting the quality of the silicide layer 62 and oxidizing the remaining silicon cap layer 88. Referring to FIG. 13, after the formation process of the silicon cap layer 88 (shown in FIG. 10), an anisotropic etching process can be carried out to remove portions of the dielectric layer 58 and the floating gate material layer 56 not covered by the hard mask layer 64 to form at least a stacked structure 91. This anisotropic etching process may also remove portions of the silicon cap layer 88 and the patterned hard mask layer 64, and the remaining floating gate material layer 56 of each stacked structure 91 forms a floating gate 84. Then, as shown in FIG. 14, a thermal process is performed to reduce the sheet resistance of word lines and oxidize the remaining silicon cap layer 88 and the sidewall surfaces of the floating gate 84, forming an oxide layer 93 and a thin oxide layer 95 at the same time.

According to the second embodiment of the present invention, the silicon cap layer 88 is formed on the sidewalls of the control gates 86 and the patterned silicide layer 62 before defining the pattern of the floating gates 84. Therefore, it provides an advantage of that the later formed floating gates 84 have a larger critical dimension (CD), further increasing the coupling ratio (CR) of the floating gates 84 and word lines, the control gates 86. In addition, the floating gate insulating layer 54 is not exposed during the thermal process, so a good quality of the floating gate insulating layer 54 can be provided.

In contrast to the prior arts, the fabrication method of a flash memory of the present invention comprises forming a thin silicon cap layer on the sidewalls of the control gate and silicide layer prior to performing the thermal process for improving the electricity quality of the silicide layer, and therefore the thermal process will not damage the silicide layer. Accordingly, the silicide layer is protected even during the sequent ash or wet etching processes, and the word lines of the present invention flash memory could have uniform profiles and structures. As a result, the problem of abnormal oxidization of the silicide layer bringing disadvantages of voids and moist is effective solved. In a word, the present invention provides a fabrication method of flash memory with good profile, high quality, and good reliability through simple processes.

Those skilled in the art will readily observe that numerous modifications and alterations of the device and method may be made while retaining the teachings of the invention.

What is claimed is:

1. A method of fabricating a flash memory, comprising:
providing a semiconductor substrate;
successively forming a floating gate insulating layer, a floating gate material layer, a dielectric layer, a control gate material layer, a silicide layer, and a hard mask layer on a surface of the semiconductor substrate;
patterning the hard mask layer;
removing portions of the silicide layer, the control gate material layer, the dielectric layer, and the floating gate material layer not covered by the patterned hard mask layer to form a stacked structure;
forming a silicon cap layer that covers the surface of the stacked structure on the semiconductor substrate; and
performing a thermal process.

2. The method of claim 1, wherein the method of forming the silicon cap layer comprises a furnace deposition process, a chemical vapor deposition (CVD) process, or an epitaxial growth process.

3. The method of claim 2, wherein a process temperature of the furnace deposition process or the CVD process is less than 600° C.

4. The method of claim 1, wherein the silicon cap layer comprises polysilicon or amorphous-silicon materials.

5. The method of claim 1, further comprising removing the remaining silicon cap layer that covers the floating gate insulating layer after performing the thermal process.

6. The method of claim 5, wherein the step of removing the remaining silicon cap layer comprises an anisotropic etching process.

7. The method of claim 1, further comprising:
forming a source on a portion of the semiconductor substrate, the source being positioned at a side of the stacked structure;
forming an erase gate insulating layer and a word line gate insulating layer on the semiconductor substrate at two sides of the stacked structure respectively; and
forming an erase gate and a word line gate on the erase gate insulating layer and the word line gate insulating layer respectively.

8. The method of claim 1, wherein the control gate material layer and the floating gate material layer both comprise polysilicon materials.

9. The method of claim 1, wherein the silicide layer comprises tungsten silicide.

10. The method of claim 1, wherein the silicon cap layer is oxidized by the thermal process so as to form an oxide layer.

11. A method of fabricating a flash memory, comprising:
providing a semiconductor substrate;
successively forming a floating gate insulating layer, a floating gate material layer, a dielectric layer, a control gate material layer, a silicide layer, and a hard mask layer on the semiconductor substrate;
patterning the hard mask layer;
removing portions of the silicide layer and the control gate material layer not covered by the patterned hard mask layer until the dielectric layer is exposed so as to form a control gate;
forming a silicon cap layer on the semiconductor substrate to cover surfaces of the sidewalls of the silicide layer and the control gate; and
performing a thermal process.

12. The method of claim 11, further comprising performing an anisotropic etching process to remove portions of the dielectric layer and the floating gate material layer not covered by the patterned hard mask layer after performing the thermal process so as to form a floating gate.

13. The method of claim 11, wherein the method of forming the silicon cap layer comprises a furnace deposition process, a CVD process, or an epitaxial growth process.

14. The method of claim 13, wherein a process temperature of the furnace deposition process or the CVD process is less than 600° C.

15. The method of claim 11, wherein the dielectric layer comprises a top silicon oxide layer, a silicon nitride layer, and a bottom silicon oxide layer.

16. The method of claim 11, wherein the silicon cap layer comprises polysilicon or amorphous silicon materials.

17. The method of claim 11, wherein the control gate material layer and the floating gate material layer both comprise polysilicon materials.

18. The method of claim 11, wherein the silicide layer comprises tungsten silicide.

19. The method of claim 11, wherein the silicon cap layer is oxidized by the thermal process so as to form an oxide layer.

20. The method of claim 11, further comprising performing an anisotropic etching process before performing the thermal process to remove portions of the dielectric layer and the floating gate material layer not covered by the patterned hard mask layer so as to form a floating gate.
